(19) United States
(12) Patent Application Publication
(10) Pub. No.: US 2008/0067692 A1
(43) Pub. Date: Mar. 20, 2008

(54) SEMICONDUCTOR DEVICES HAVING CONTACT PAD PROTECTION FOR REDUCED ELECTRICAL FAILURES AND METHODS OF FABRICATING THE SAME

(75) Inventors: Jae-Hun Kim, Gyeonggi-do (KR); Byung-Yoon Kim, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/854,093

(22) Filed: Sep. 12, 2007

(30) Foreign Application Priority Data
Sep. 20, 2006 (KR) 10-2006-0091321

(51) Int. Cl. H01L 23/52; H01L 21/4763

(52) U.S. Cl. 257/774; 438/653; 257/E23.141; 257/E21.495

(57) ABSTRACT

A semiconductor device includes contact pads formed in a first interlayer insulating layer on a semiconductor substrate, contact pad protecting patterns covering edges of a surface of the contact pads, and conductive lines positioned on a second interlayer insulating layer covering the contact pad protecting patterns and selectively connected to the contact pads.

### CROSS-REFERENCE TO RELATED APPLICATION

This application claims priority under 35 U.S.C. § 119 to Korean Patent Application No. 10-2006-0091321 filed on Sep. 20, 2006 in the Korean Intellectual Property Office, the disclosure of which is incorporated herein by reference in its entirety.

### BACKGROUND OF THE INVENTION

1. Field of the Invention

The present invention relates to semiconductor devices and methods of fabricating the same, and, more particularly, to semiconductor devices that can reduce and/or prevent electrical contact failures, and methods of fabricating the same.

2. Description of the Related Art

Higher integration in semiconductor devices has generally resulted in a decrease in the size of a contact hole that connects one element to another element or one layer to another layer, while increasing the thickness of an inter-level dielectric layer. Thus, the aspect ratio of the contact hole, i.e., the ratio between its height to its diameter, increases and an alignment margin of the contact hole decreases in a photolithography process. As a result, the formation of small contact holes by conventional methods may become difficult.

For this reason, the size of a buried contact (BC) serving as a storage node contact is also decreased, thereby the depth thereof becomes gradually smaller from an upper part to a lower part, and the contact hole is not completely formed. Accordingly, to increase the size of the buried contact, the contact hole may be expanded by performing a wet etching process on the contact hole after a formation of the contact hole. Meanwhile, as the integration of semiconductor devices increases, the size of a bit line is reduced, and a margin for insulating an underlying pad may become insufficient during the wet etch process performed for the purpose of increasing the size of the buried contact, thereby partially exposing an adjacent pad. Accordingly, an etching solution may penetrate through a direct contact (DC) that electrically connects the bit line to an underlying contact pad, so that a conductive material may be etched.

Therefore, the direct contact (DC) of the underlying bit line may be partially filled with an insulating material or a conductive material of a buried contact (BC) in a subsequent process, thereby resulting in unwanted electrical contact failures.

### SUMMARY OF THE INVENTION

According to some embodiments of the present invention, a semiconductor device includes contact pads formed in a first interlayer insulating layer on a semiconductor substrate, contact pad protecting patterns covering edges of a surface of the contact pads, and conductive lines positioned on a second interlayer insulating layer covering the contact pad protecting patterns and selectively connected to the contact pads.

According to other embodiments of the present invention, a semiconductor device is fabricated by forming contact pads in a first interlayer insulating layer on a semiconductor substrate, forming a contact pad protecting layer covering a surface of the contact pads, forming a second interlayer insulating layer covering the contact pad protecting layer on the contact pad protecting layer, forming conductive lines selectively connected to the contact pads on the second inter-level dielectric layer, and forming contact pad protecting patterns covering edges of a surface of the contact pads by etching the second interlayer insulating layer between the conductive lines and the contact pad protecting layer.

According to still other embodiments of the present invention, a semiconductor device is fabricated by forming gate lines extending in one direction on a first interlayer insulating layer on a semiconductor substrate, forming first and second contact pads between the gate lines, forming a contact pad protecting layer on a surface of the first interlayer insulating layer and the first and second contact pads, forming bit lines positioned on a second interlayer insulating layer provided on the contact pad protecting layer, extending in a direction perpendicular to the gate lines and connected to the first contact pad, forming expanded contact openings in the second interlayer insulating layer between the bit lines, partially exposing the contact pad protecting layer and extending in a direction of the bit lines, forming contact spacers on internal walls of the expanded contact openings and simultaneously forming expanded contact holes exposing the second contact pad, and forming expanded contact plugs by filling the expanded contact holes with a conductive material.

### BRIEF DESCRIPTION OF THE DRAWINGS

Other features of the present invention will be more readily understood from the following detailed description of exemplary embodiments thereof when read in conjunction with the accompanying drawings, in which:

FIG. 1 is a layout view of a semiconductor device according to some embodiments of the present invention;

FIG. 2A is a cross-sectional view of the semiconductor device shown in FIG. 1 taken along the line II-II′;

FIGS. 2B through 2J are cross-sectional views sequentially illustrating operations for fabricating the semiconductor device shown in FIG. 2A according to some embodiments of the present invention;

FIG. 3A is a cross-sectional view illustrating a cell area and a peripheral area of a semiconductor device according to some embodiments of the present invention; and

FIGS. 3B through 3H are cross-sectional views sequentially illustrating operations for fabricating the semiconductor device shown in FIG. 3A according to some embodiments of the present invention.

### DETAILED DESCRIPTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout the description of the figures.

It will be understood that when an element is referred to as being “on” another element, it can be directly on the other element or intervening elements may be present. In contrast, when an element is referred to as being “directly on” another element, there are no intervening elements present. It will be understood that when an element is referred to as being “connected” or “coupled” to another element, it can be directly connected or coupled to the other element or intervening elements may be present. In contrast, when an element is referred to as being “directly connected or coupled” to another element, there are no intervening elements present. Furthermore, “connected” or “coupled” as used herein may include wirelessly connected or coupled. As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another. For example, a first layer could be termed a second layer, and, similarly, a second layer could be termed a first layer without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to other elements as illustrated in the Figures. It will be understood that relative terms are intended to encompass different orientations of the device in addition to the orientation depicted in the Figures. For example, if the device in one of the figures were turned over, elements described as being on the “lower” side of other elements would then be oriented on “upper” sides of the other elements. The exemplary term “lower”, can therefore, encompass both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

In the description, a term “substrate” used herein may include a structure based on a semiconductor, having a semiconductor surface exposed. It should be understood that such a structure may contain silicon, silicon on insulator, silicon on sapphire, doped or undoped silicon, epitaxial layer supported by a semiconductor substrate, or another structure of a semiconductor. And, the semiconductor may be silicon-germanium, germanium, or germanium arsenide, not limited to silicon. In addition, the substrate described hereinafter may be one in which regions, conductive layers, insulation layers, their patterns, and/or junctions are formed.

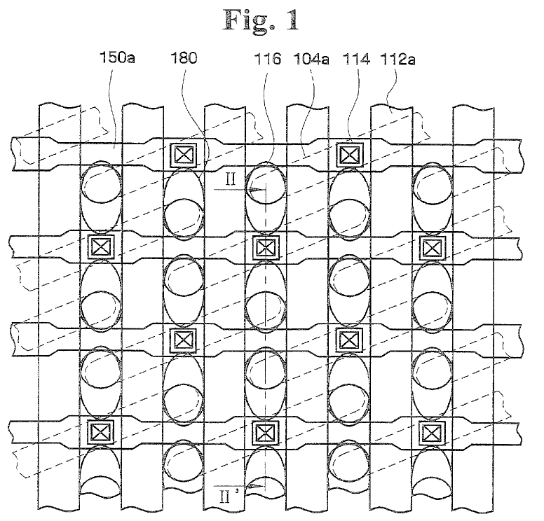

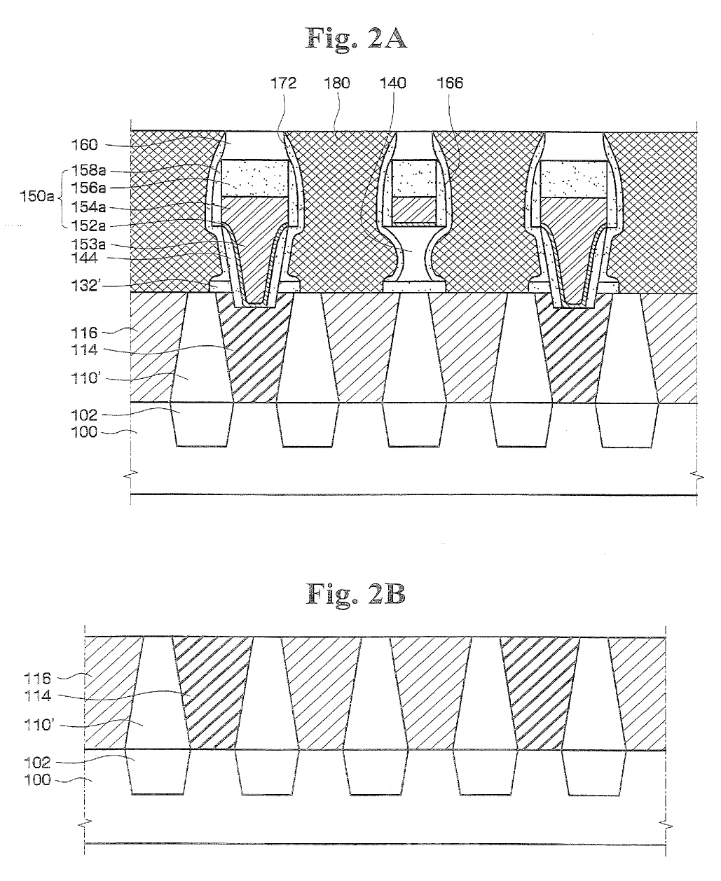

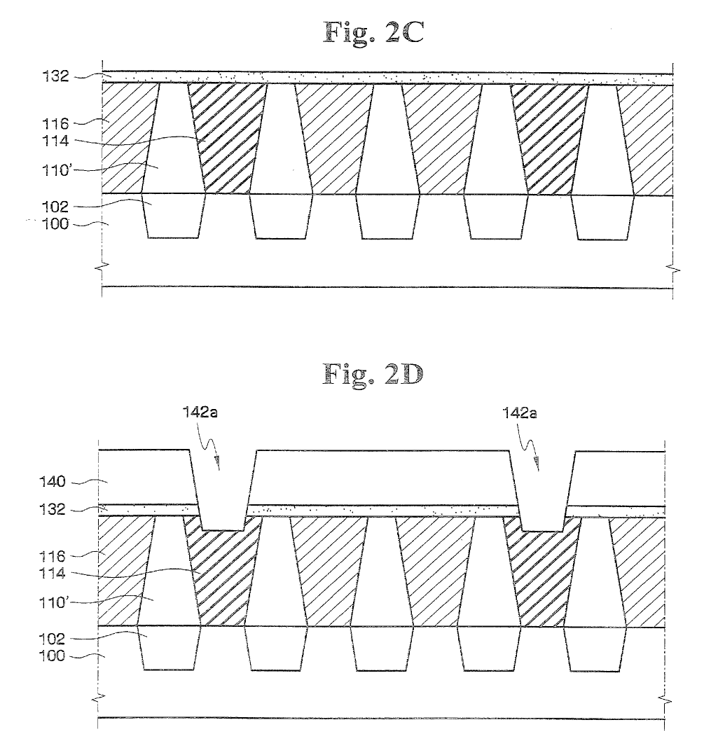

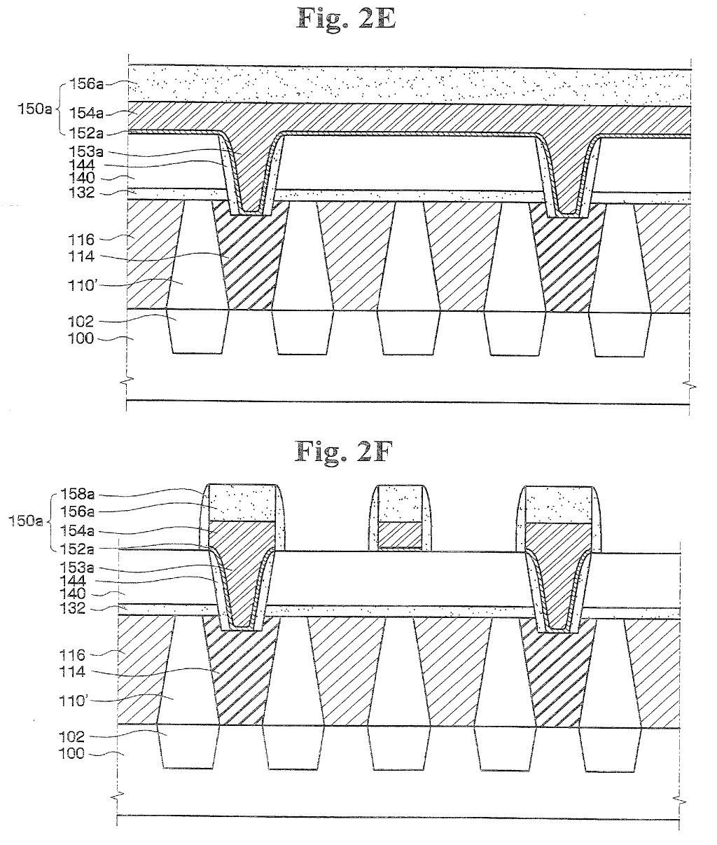

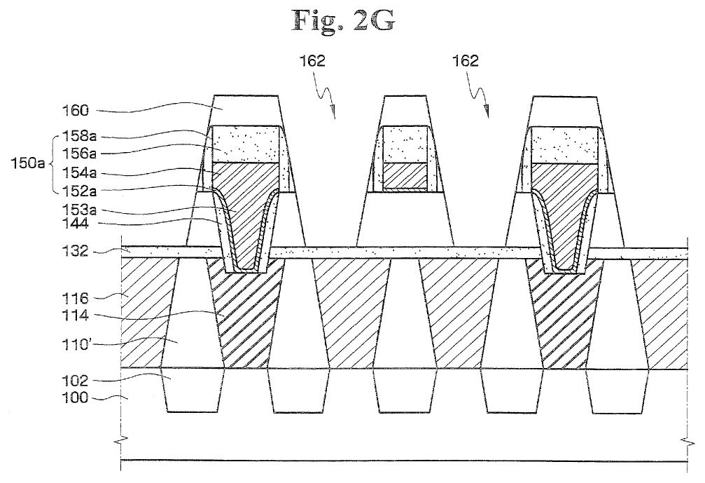

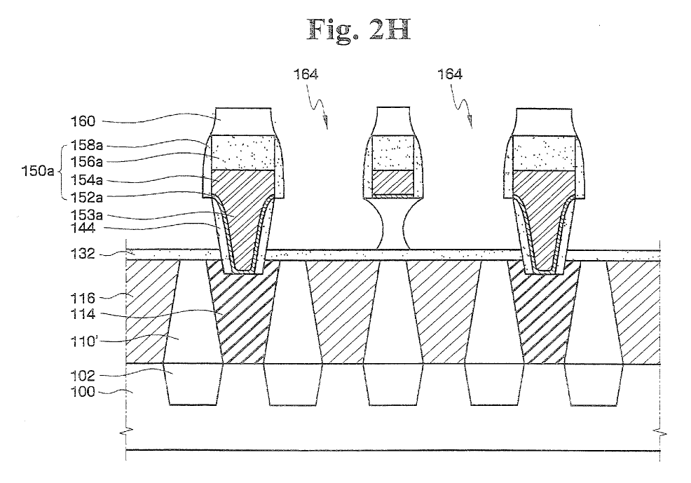

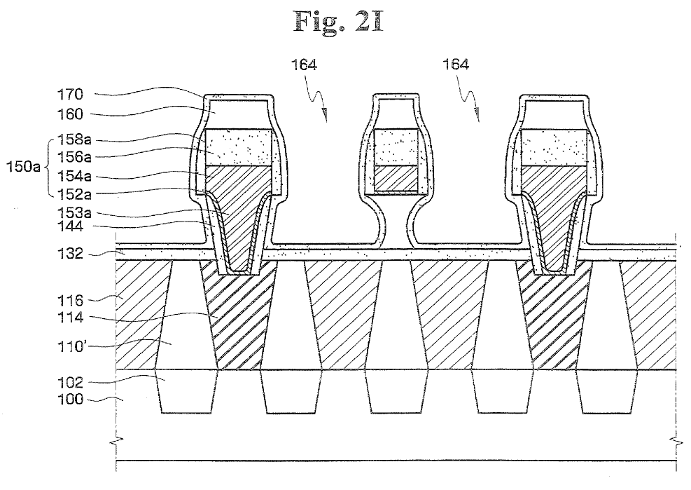

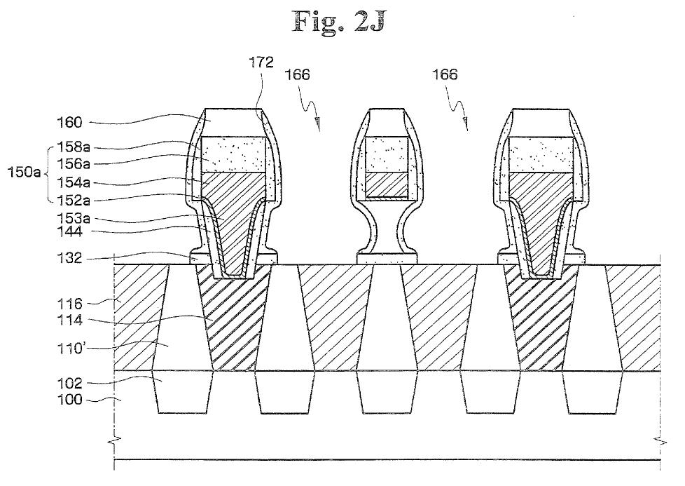

FIG. 1 is a layout view of a semiconductor device according to some embodiments of the present invention, and FIG. 2A is a cross-sectional view of the semiconductor device shown in FIG. 1 taken along the line II-II′.

Referring to FIGS. 1 and 2A, a semiconductor substrate 100 includes active regions 104 defined by isolation films 102, and a plurality of gate lines 112a extending in one direction are disposed on the semiconductor substrate 100. Impurity regions (not shown) are formed in the active regions 104 at both sides of each of the gate lines 112a.

A first interlayer insulating layer 110′ is formed on the gate lines 112a, and contact pads 114 and 116 are formed in the first interlayer insulating layer 110′ between the gate lines 112a. The contact pads 114 and 116 are formed of a conductive material, such as polysilicon or a metallic material. The contact pads 114 and 116 may be self-aligned contact (SAC) pads with respect to the gate lines 112a.

The contact pads can be divided into a bit line contact pad 114 electrically connected to an upper bit line 150 and a storage node contact pad 116 electrically connected to an upper storage node (not shown).

A contact pad protecting layer pattern 132′ is formed on the bit line contact pad 114. In more detail, the contact pad protecting layer pattern 132′ covers peripheral portions of the surface of the bit line contact pad 114 and encloses a lower portion of a bit line contact plug 153a positioned over the bit line contact pad 114. Accordingly, the bit line contact pad 114 and a storage node contact plug 180 positioned adjacent to the bit line contact pad 114 are electrically disconnected from each other. In other embodiments, the contact pad protecting layer pattern 132′ may partially cover the surface of the storage node contact pad 116. Accordingly, adjacent storage node contact plugs are electrically disconnected from each other.

A second interlayer insulating layer 140 is formed on the contact pad protecting layer pattern 132′. The bit line contact plug 153a electrically connected to the bit line contact pad 114 is formed in the second interlayer insulating layer 140.

Bit line contact spacers 144 made of silicon nitride layer are formed on both sidewalls of the bit line contact plug 153a. The contact pad protecting layer pattern 132′ is formed below the bit line contact plug 153a, covering the peripheral portions of the surface of the bit line contact pad 114 and enclosing a lower portion of the bit line contact plug 153a positioned over the bit line contact pad 114.

The bit line contact plug 153a may be formed of a conductive layer. In such a case, a metal barrier layer 152a may be positioned under the metal layer. A metal silicide layer (not shown) may be formed at an interface between the metal barrier layer 152a and the bit line contact pad 114.

When the metal silicide layer is formed at the interface between the metal barrier layer 152a and the bit line contact pad 114, the bit line contact plug 153a may be recessed into the bit line contact pad 114 to a predetermined depth so as not to be exposed outside the bit line contact pad 114.

A plurality of bit lines 150a are positioned on the second interlayer insulating layer 140, the plurality of bit lines 150a being connected to the bit line contact plug 153a and extending in a direction perpendicular to the underlying gate lines 112a.

Each of the plurality of bit lines 150a includes a stack of a conductive layer 154a and a capping layer 156a for forming a bit line, and a spacer 158a is formed on side walls of the conductive layer 154a and the capping layer 156a. The bit line conductive layer 154a may also be formed of a conductive layer, like the bit line contact plug 153a, in other embodiments.

A third interlayer insulating layer 160 is positioned on the plurality of bit lines 150a. A storage node expanded contact hole 166, which exposes the underlying storage node contact pad 116, is formed through the second and third inter-level dielectric layers 140 and 160. The storage node expanded contact hole 166 is formed so as to extend in a direction toward the bit lines 150a in the second interlayer insulating layer 140 until it exposes side walls of the bit line contact spacers 144 of the bit line contact plug 153a.

A storage node contact spacer 172 is formed on internal walls of the storage node expanded contact hole 166, and the storage node contact plug 180 made of a conductive material is formed in the storage node expanded contact hole 166. The storage node contact spacer 172 may be positioned on the contact pad protecting layer pattern 132′. Thus, a portion of the contact pad protecting layer pattern 132′ may become a lower portion of the storage node contact spacer 172.

Because the storage node contact plug 180 is formed in the storage node expanded contact hole 166, a contact area between the storage node contact plug 180 and the storage node contact pad 114 increases. In addition, use of the storage node contact spacer 172 may reduce and/or prevent a bridge phenomenon from occurring between each of adjacent storage node contact plugs 180.

The structure of a semiconductor device according to some embodiments of the present invention will be described in greater detail with reference to FIGS. 1 and 2A. FIG. 2A is a cross-sectional view illustrating a cell area and a peripheral area of a semiconductor device, according to some embodiments of the present invention, in which the cell cross-section is taken along the line II-II′ of FIG. 1. For brevity, components each having the same function for describing the embodiments shown in FIG. 2A are respectively identified by the same reference numerals, and their repetitive description will be omitted.

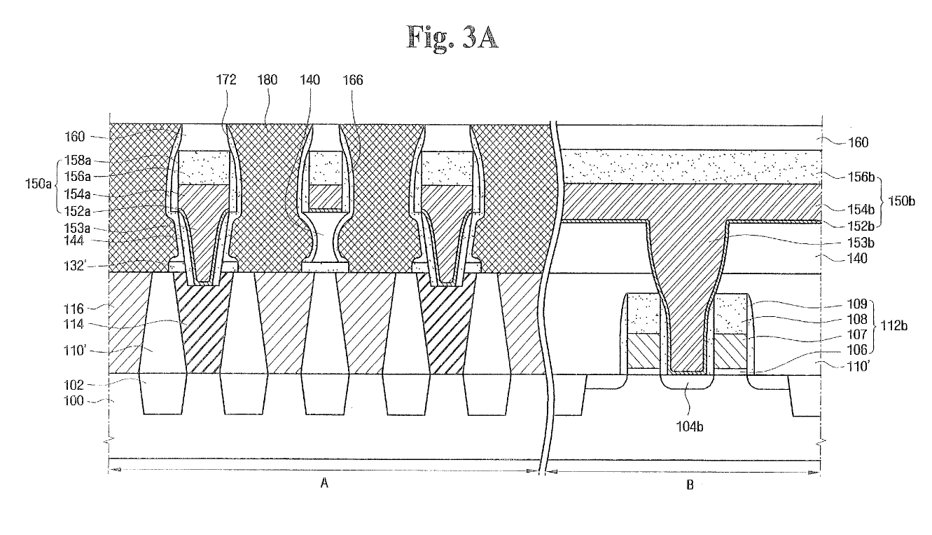

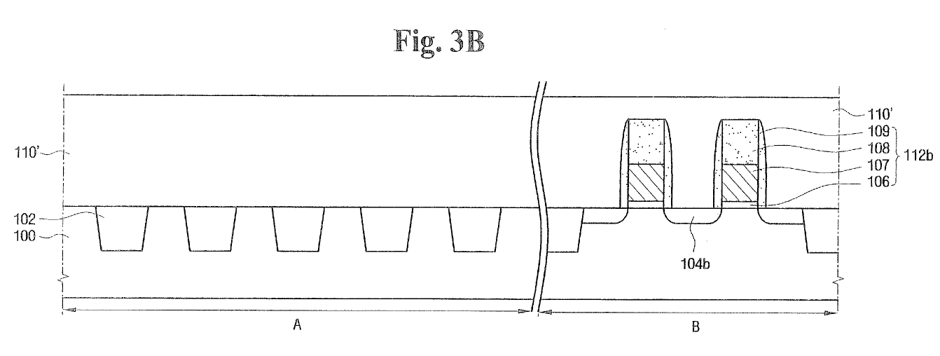

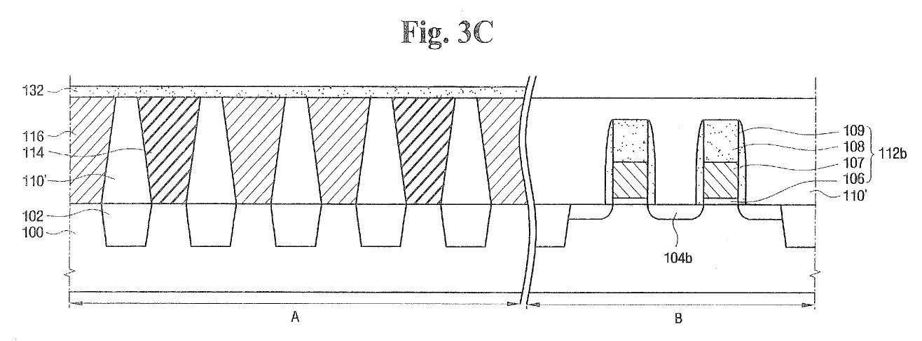

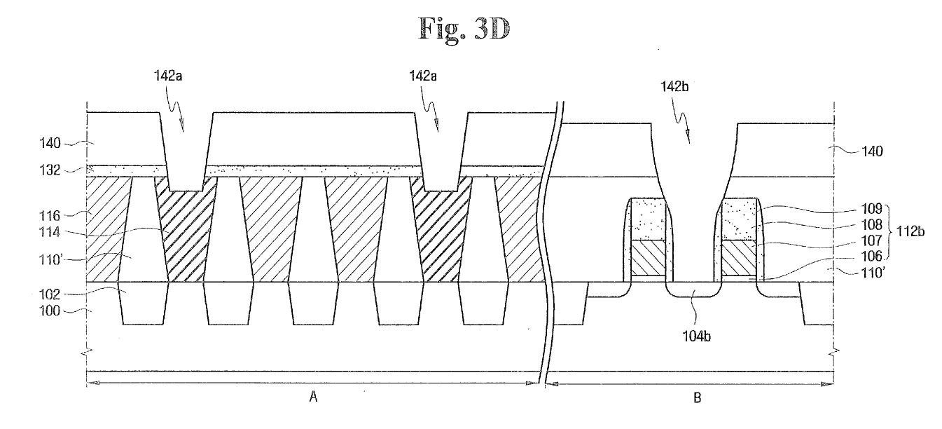

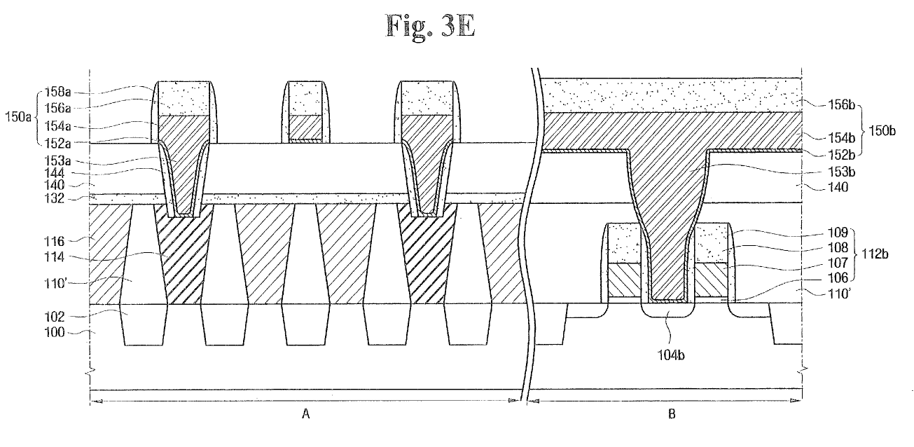

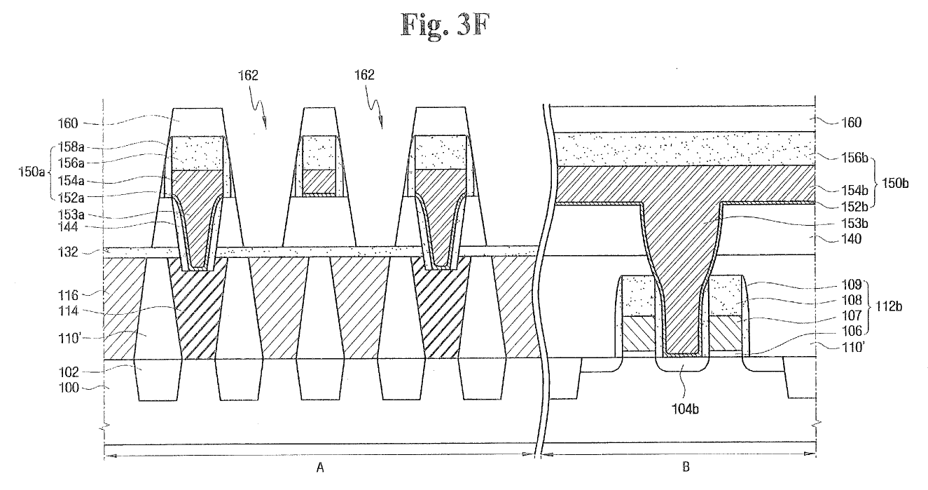

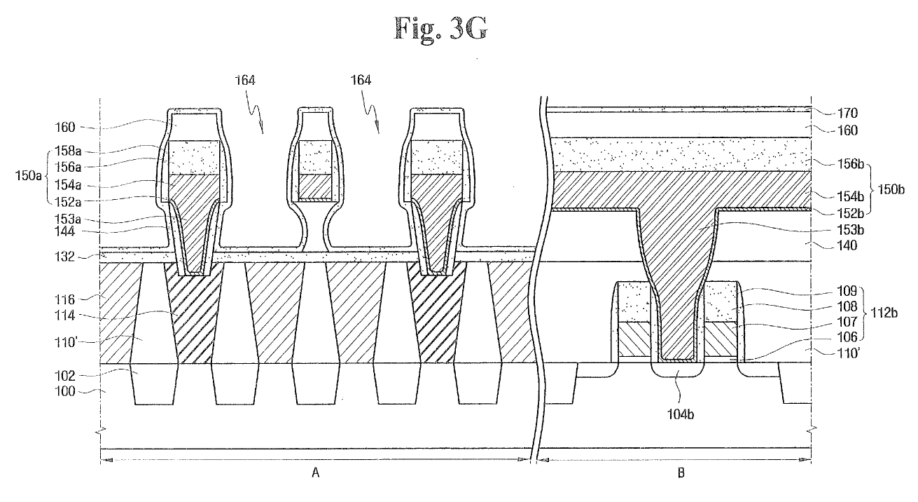

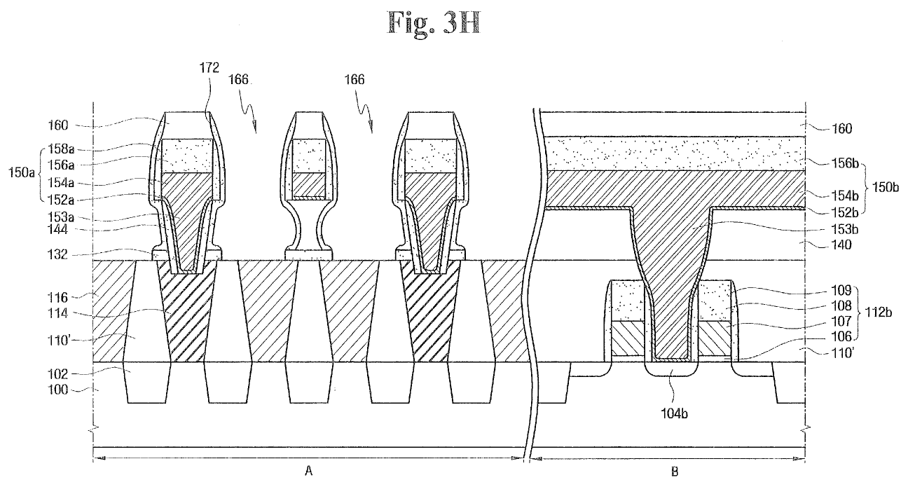

As shown in FIG. 3A, the semiconductor substrate 100 includes a cell region A and a peripheral circuit area B defined therein. Various elements each having substantially the same structure as in the embodiments discussed above are formed in the cell area A of the semiconductor substrate 100.

Active regions are defined by isolation films 102 in the peripheral circuit area B of the semiconductor substrate 100, like in the cell area A. NMOS transistors, PMOS transistors, and the like, are formed in the peripheral circuit area B of the semiconductor substrate 100.

In the peripheral circuit area B, a gate electrode 112b is formed on the same level as the gate lines 112a formed on the cell area A and have the same structure as the gate lines 112a. That is, the gate electrode 112b comprises a gate-insulating layer 106, a gate conductive layer 107, a gate capping layer 108, and a gate spacer 109. Impurity regions 104b are formed in the semiconductor substrate 100 between adjacent gate electrodes 112b.

First and second inter-level dielectric layers 110′ and 140 are stacked on the gate electrode 112b of the peripheral circuit area B. A wiring contact plug 153b connected to the impurity regions 104b of the peripheral circuit area B are formed through the first and second inter-level dielectric layers 110′ and 140.

The wiring contact plug 153b is formed of a conductive layer, like the bit line contact plug 153a. When the wiring contact plug 153b is formed of a metal layer, a metal barrier layer 152b is positioned under the metal layer. The wiring contact plug 153b formed in the peripheral circuit area B is self-aligned to the gate electrode 112b and a width of the wiring contact plug 153b is gradually reduced toward its lower portion.

A wiring 150b connected to the wiring contact plug 153b is positioned on the second interlayer insulating layer 140 of the peripheral circuit area B. That is to say, the wiring 150b may be formed on the same level as the bit lines 150a of the cell area A and may have the same stacked structure as the bit lines 150a. A third interlayer insulating layer 160 is positioned on the wiring contact plug 153b formed on the peripheral circuit area B.

Methods of fabricating a semiconductor device, according to some embodiments of the present invention, will be described with reference to FIGS. 1 and 2B through 2J, together with FIG. 2A. FIGS. 2B through 2J are cross-sectional views sequentially illustrating operations for fabricating the semiconductor device shown in FIG. 2A according to some embodiments of the present invention.

As shown in FIG. 2B, an isolation film 102 is formed on a semiconductor substrate 100 using a local oxidation of silicon (LOCOS) process or a shallow trench isolation (STI) process to define an active region 104 in the semiconductor substrate 100.

A plurality of gate lines 112a, which extend in one direction across the active region 104 defined on the semiconductor substrate 100, is formed on the semiconductor substrate 100.

An insulation material is deposited on an entire surface of the semiconductor substrate 100 having the plurality of gate lines 112a and an upper portion of the surface of the semiconductor substrate 100 is planarized using a chemical-mechanical polishing (CMP) process or an etch-back process, thereby forming a potential first interlayer insulating layer 110. The potential first interlayer insulating layer 110 may be formed of silicon oxide.

Next, the potential first interlayer insulating layer 110 is etched using a general photolithography process to form contact holes exposing impurity regions (not shown) in the semiconductor substrate 100. When the contact holes are formed by etching the potential first interlayer insulating layer 110 using an etching gas having a high etching selectivity with respect to the gate lines 112a, the contact holes are self-aligned to the gate lines 112a and the impurity regions (not shown) formed in the semiconductor substrate 100 are exposed.

Then, a conductive material, such as polysilicon highly doped with impurities or a metallic material, is deposited on an entire surface of the semiconductor substrate 100 having the contact holes to form a conductive layer filling the contact holes. Subsequently, an upper portion of the conductive layer is planarized to expose an upper portion of the potential first interlayer insulating layer 110, thereby forming self-aligned contact (SAC) pads 114 and 116 in the potential first interlayer insulating layer 110. The SAC pads 114 and 116 may be divided into a bit line contact pad 114 and a storage node contact pad 116.

As shown in FIG. 2C, a contact pad protecting layer 132 is formed on the SAC contact pads 114 and 116 to entirely cover the first interlayer insulating layer 110′ and the SAC pads 114 and 116. The contact pad protecting layer 132 is formed by depositing a silicon nitride layer made of e.g., silicon nitride (SiN) or silicon oxynitride (SiON), on the SAC contact pads 114 and 116. The contact pad protecting layer 132 may reduce and/or prevent damage to the SAC contact pads 114 and 116 during subsequent processes.

Next, as shown in FIG. 2D, the second interlayer insulating layer 140 is formed on the contact pad protecting layer 132, and the second interlayer insulating layer 140 and the contact pad protecting layer 132 are etched using a general photolithography process to form a bit line contact hole 142a.

In more detail, the second interlayer insulating layer 140 is formed by depositing a silicon oxide based material such as borosilicate glass (BSG), phosphorous silicate glass (PSG), borophosphorous silicate glass (BPSG), plasma enhanced tetraethyl orthosilicate (PE-TEOS), high density plasma (HDP) oxide, or the like.

The bit line contact hole 142a is formed by partially etching the second interlayer insulating layer 140 and the contact pad protecting layer 132 to expose the underlying bit line contact pad 114. The bit line contact hole 142a exposes a central portion of the bit line contact pad 114. Here, the bit line contact hole 142a may be recessed into the bit line contact pad 114 by partially etching the bit line contact pad 114.

As shown in FIG. 2E, a nitride layer for forming spacers is deposited on an entire surface of the resultant structure having the bit line contact hole 142a and is anisotropically etched to form a bit line contact spacer 144.

A conductive material may be deposited on the bit line contact hole 142a to fill the same, thereby forming the bit line contact plug 153a. The conductive material is deposited thickly enough to planarize the upper portion of the second interlayer insulating layer 140, thereby forming the bit line conductive layer 154a together with the bit line contact plug 153a.

In some embodiments, the bit line contact plug 153a may be formed of a metal layer made of, for example, tungsten (W), copper (Cu), aluminum (Al), or the like. Before forming the metal layer, the metal barrier layer 152a may be formed thinly in order to reduce or prevent diffusion of a metallic material or reduce contact resistance. The metal barrier layer 152a may comprise Ta, TaN, TaSiN, Ti, TiN, TiSiN, W, and/or WN, in accordance with various embodiments of the present invention. When the bit line contact plug 153a is formed in such a manner, a metal silicide layer (not shown) may be formed at an interface between the metal barrier layer 152a and the bit line contact pad 114.

After forming the bit line conductive layer 154a, a nitride layer is deposited on the bit line conductive layer 154a to form the capping layer 156a.

Next, as shown in FIG. 2F, the bit line conductive layer 154a and the capping layer 156a are patterned to form the plurality of bit lines 150a extending in a direction perpendicular to the underlying gate lines 112a. Each of the bit lines 150a includes the bit line spacer 158a formed on the sidewalls of the patterned bit line conductive layer 154a and capping layer 156a. The bit line spacer 158a is formed by depositing a nitride layer on an entire surface of the resultant structure formed after patterning the bit line conductive layer 154a and the capping layer 156a, and performing an etch-back process thereon.

Thereafter, an insulating material is deposited on the second interlayer insulating layer 140 having the bit lines 150a and planarized to form the third interlayer insulating layer 160. The third interlayer insulating layer 160 may be formed of a silicon oxide based material such as borosilicate glass (BSG), phosphorous silicate glass (PSG), borophosphorous silicate glass (BPSG), plasma enhanced tetraethyl orthosilicate (PE-TEOS), high density plasma (HDP) oxide, or the like.

Then, as shown in FIG. 2G, a mask pattern (not shown) is formed on the third interlayer insulating layer 160 to expose the storage node contact pad 116. The second and third interlayer insulating layers 140 and 160 are etched using a dry etch process and the mask pattern. Here, the contact pad protecting layer 132 positioned on the storage node contact pad 116 is used as a stopper during the dry etch process and a storage node contact opening 162 is formed to expose the contact pad protecting layer 132 on the storage node contact pad 116. Because the storage node contact opening 162 has a relatively large aspect ratio, a width of the storage node contact opening 162 is gradually reduced toward its lower portion.

To increase the width of its lower portion, the storage node contact opening 162 is etched using a wet etch process. During the wet etch process, a mixed solution of ammonia (NH₄OH), hydrogen peroxide (H₂O₂), and deionized (DI) water, and/or a hydrogen fluoride (HF) solution may be used as an etchant.

As a result, as shown in FIG. 2H, the storage node contact opening 162 extends in the direction of the bit lines 150a, thereby forming a storage node expanded contact opening 164. Because the contact pad protecting layer 132 is disposed as an underlying layer of the resultant product of the wet etch process, it can be used as an etch stopper, so that the contact pads 114 and 116 are not exposed. In addition, because the bit line contact spacers 144 are formed on the sidewalls of the bit line contact plug 153a, it is possible to prevent or reduce the likelihood that the bit line contact plug 153a is exposed when the storage node contact opening 162 extends. Thus, the bit line contact plug 153a and the SAC contact pads 114 and 116 can be protected from damage by the etchant when the storage node expanded contact opening 164 is formed.

As shown in FIG. 2I, a contact spacer insulating layer 170 is conformally deposited on a surface of the resultant product. The contact spacer insulating layer 170 may be formed by depositing silicon nitride to a thickness of about 100 to about 300 Å.

As shown in FIG. 2J, an etch-back process is performed on the conformally deposited contact spacer insulating layer 170 to form a storage node contact spacer 172 on internal walls of the storage node expanded contact opening 164. The etch-back process is performed until an upper portion of the underlying contact pad protecting layer 132 is exposed to form the storage node expanded contact hole 166 exposing the storage node contact pad 116. The contact pad protecting layer 132 that is not etched back during formation of the storage node expanded contact hole 166 remains as the contact pad protecting layer pattern 132′. Accordingly, the storage node expanded contact hole 166 can be formed without damage to the bit line contact plug 153a and the bit line contact pad 114.

Next, referring back to FIG. 2A, the storage node expanded contact hole 166 is filled with a conductive material (e.g., a metallic material and planarized, thereby completing the storage node contact plug 180. In other words, the resultant storage node contact plug 180 has an increased contact area with the underlying storage node contact pad 116 while avoiding damage to the bit line contact plug 153a.

Methods of fabricating a semiconductor device according to further embodiments of the present invention will be described with reference to FIGS. 1, 3B through 3H, together with FIG. 3A. FIGS. 3B through 3H are cross-sectional views sequentially illustrating operations in fabricating the semiconductor device shown in FIG. 3A. For brevity, components each having the same function for describing the embodiments shown in FIGS. 2B through 2J are respectively identified by the same reference numerals, and their repetitive description will be omitted.

Referring to FIG. 3B, a semiconductor substrate 100 includes a cell region A and a peripheral circuit area B defined therein. Active regions are defined by isolation films 102 in the respective areas A and B of the semiconductor substrate 100.

Gate lines 112a are formed on the active area A of the semiconductor substrate 100 while gate electrodes 112b are formed on the peripheral circuit area B of the semiconductor substrate 100.

In more detail, gate patterns each including a gate insulating layer 106, a gate conductive layer 107, and a gate capping layer 108 sequentially stacked are formed on the active area A and the peripheral circuit area B of the semiconductor substrate 100. Then, boron (B) or phosphorus (P) ion implantation is performed on the semiconductor substrate 100 using the gate patterns as ion implantation masks to form impurity regions (not shown).

A nitride layer is deposited on an entire surface of the semiconductor substrate 100 and anisotropically etched to form the gate spacer 109, thereby completing the gate lines 112a and the gate electrodes 112b.

NMOS transistors, PMOS transistors, and the like, may be formed on the peripheral circuit area B of the semiconductor substrate 100, and the respective gates of the NMOS and PMOS transistors may be dual gates doped with impurities of different conductivity types.

After forming the gate lines 112a and the gate electrodes 112b in the above-described manner, an oxide based insulation material is deposited on an entire surface of the semiconductor substrate 100 and an upper portion of the surface of the semiconductor substrate 100 is planarized using an etch-back process, thereby forming a first interlayer insulating layer 110′. The first interlayer insulating layer 110′ may be formed of silicon oxide.

Next, as shown in FIG. 3C, contact (SAC) pads 114 and 116 are formed in the first interlayer insulating layer 110′ of the cell area A. The pads 114 and 116 can be formed using the same process as described in the previous embodiments discussed above with reference to FIG. 2B.

Then, a contact pad protecting layer 132 is formed by depositing a contact pad protecting nitride layer on the first interlayer insulating layer 110′ of the cell area A and the peripheral circuit area B and patterning the same, the contact pad protecting layer 132 covering surfaces of the first interlayer insulating layer 110′ of the cell area A and the contact pads 114 and 116. The contact pad protecting layer 132 may be formed by depositing a nitride layer made of, e.g., silicon nitride (SiN) or silicon oxynitride (SiON), on the contact pads 114 and 116.

Next, as shown in FIG. 3D, the second interlayer insulating layer 140 is formed on the contact pad protecting layer 132 of the cell area A and the first interlayer insulating layer 110′ of the peripheral circuit area B.

Then, the second interlayer insulating layer 140 is etched using a general photolithography process to form a bit line contact hole 142a in the cell area A while forming a wiring contact hole 142b.

The formation of the bit line contact hole 142a in the cell area A may be performed in the same manner as described above with reference to FIG. 2D.

During the formation of the bit line contact hole 142a in the cell area A, the wiring contact hole 142b can also be formed by etching the first interlayer insulating layer 110′ and the second interlayer insulating layer 140 of the peripheral circuit area B using a general photolithography process. The wiring contact hole 142b formed in the peripheral circuit area B can expose an impurity region 104 in the semiconductor substrate 100 or the gate electrode 112b. The wiring contact hole 142b may be self-aligned to the underlying gate electrode 112b. As described above, because the contact pad protecting layer 132 is not formed on the first interlayer insulating layer 110′ of the peripheral circuit area B during the formation of the wiring contact hole 142b, unlike in the cell area A, the wiring contact hole 142b can be easily formed.

As shown in FIG. 3E, a bit line contact spacer 144 is formed on sidewalls of the bit line contact hole 142a. At this stage, a contact spacer may also be formed on sidewalls of the wiring contact hole 142b.

Next, a conductive material may be deposited on the bit line contact hole 142a and the wiring contact hole 142b to fill the same, thereby forming a bit line contact plug 153a and a wiring contact plug 153b. The conductive material is deposited thickly enough to planarize the upper portion of the second interlayer insulating layer 140, thereby forming a wiring conductive layer 154b together with the bit line conductive layer 154a.

In more detail, the bit line contact plug 153a and the wiring contact plug 153b may be formed of a metal layer made of, for example, tungsten (W), copper (Cu), and/or aluminum (Al), or the like. Before forming the metal layer, metal barrier layers 152a and 152b may be formed thinly to reduce or prevent diffusion of a metallic material and/or reduce contact resistance. The metal barrier layers 152a and 152b may be formed of Ta, TaN, TaSiN, Ti, TiN, TiSiN, W, and/or WN, in accordance with various embodiments of the present invention. When the bit line contact plug 153a and the wiring contact plug 153b are formed in such a manner, a metal silicide layer (not shown) may be formed at an interface between the metal barrier layers 152a and 152b and the bit line contact pad 114 and the active regions.

After forming the bit line conductive layer 154a and the wiring conductive layer 154b, a nitride layer is deposited on the bit line conductive layer 154a and the wiring conductive layer 154b to form capping layers 156a and 156b.

Next, the bit line conductive layer 154a, the wiring conductive layer 154b and the capping layers 156a and 156b are patterned to form the plurality of bit lines 150a in the cell area A while forming the wirings 150b in the peripheral circuit area B.

In more detail, the bit lines 150a in the cell area A extend in a direction perpendicular to the underlying gate lines 112a and are patterned to be electrically connected to the bit line contact plug 153a. Each of the bit lines 150a includes a bit line spacer 158a formed on the side walls of the patterned bit line conductive layer 154a and capping layer 156a.

The wirings 150b in the peripheral circuit area B are patterned to be electrically connected to the wiring contact plug 153b so that they are formed at the same time with the bit lines 150a.

Thereafter, an insulating material is deposited on the second interlayer insulating layer 140 having the bit lines 150a and the wirings 150b and planarized to form a third interlayer insulating layer 160.

Then, as shown in FIGS. 3F through 3H, together with FIG. 3A, a storage node contact plug formation process is performed on the cell area A. As a result, a storage node contact plug 180 having an increased contact area with the underlying storage node contact pad 116 is obtained while avoiding damage to the bit line contact plug 153a.

A method of forming the storage node contact plug 180 having an increased contact area with the underlying storage node contact pad 116 is substantially the same as in the previous embodiments described in detail with reference to FIGS. 2G and 2J, and a repetitive explanation will not be given.

As described above, according to some embodiments of the present invention, because a contact pad protecting layer is formed on contact pads, the damage to contact pads caused by a subsequent wet etch process can be reduced or prevented.

That is to say, the contact pad protecting layer can reduce or prevent an etching solution from penetrating into a surface of a bit line contact pad during the wet etch process for forming a storage node expanded contact hole, thereby reducing or preventing electric contact failures of a semiconductor device, which may occur when the bit line contact pad is etched.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

That which is claimed:

1. A semiconductor device, comprising:
contact pads formed in a first interlayer insulating layer on a semiconductor substrate;
contact pad protecting patterns covering edges of a surface of the contact pads; and
conductive lines positioned on a second interlayer insulating layer covering the contact pad protecting patterns and selectively connected to the contact pads.

2. The semiconductor device of claim 1, wherein the contact pad protecting patterns comprise a nitride layer.

3. The semiconductor device of claim 1, further comprising contact plugs selectively connecting the conductive lines to the contact pads.

4. The semiconductor device of claim 3, wherein the contact pad protecting patterns enclose lower portions of the contact plugs.

5. The semiconductor device of claim 3, wherein each of the contact plugs comprises a metal barrier layer and a metal layer stack.

6. The semiconductor device of claim 1, further comprising:
expanded contact holes formed in the second interlayer insulating layer between the conductive lines and exposing contact pads that are not connected to the conductive lines;
contact spacers formed on internal walls of the expanded contact holes and positioned on the contact pad protecting patterns; and
expanded contact plugs buried in the expanded contact holes.

7. The semiconductor device of claim 1, wherein the semiconductor substrate comprises a cell area and a peripheral area defined therein.

8. The semiconductor device of claim 7, wherein the contact pads are formed on the cell area.

9. A method of fabricating a semiconductor device, comprising:
forming contact pads in a first interlayer insulating layer on a semiconductor substrate;
forming a contact pad protecting layer covering a surface of the contact pads;
forming a second interlayer insulating layer covering the contact pad protecting layer on the contact pad protecting layer;
forming conductive lines selectively connected to the contact pads on the second interlayer insulating layer; and
forming contact pad protecting patterns covering edges of a surface of the contact pads by etching the second interlayer insulating layer between the conductive lines and the contact pad protecting layer.

10. The method of claim 9, wherein the contact pad protecting layer comprises a nitride layer.

11. The method of claim 9, further comprising:
before forming the conductive lines:
forming contact plugs selectively connecting the conductive lines to the contact pads, wherein forming the conductive lines comprises patterning the conductive lines to be electrically connected to the contact plugs.

12. The method of claim 11, wherein each of the contact plugs comprises a metal barrier layer and a metal layer stack.

13. The method of claim 9, wherein the semiconductor substrate comprises a cell area and a peripheral area defined therein.

14. The method of claim 13, wherein the contact pad protecting layer is formed on the first interlayer insulating layer of the cell area and the contact pads.

15. A method of fabricating a semiconductor device, comprising:
forming gate lines extending in one direction on a first interlayer insulating layer on a semiconductor substrate, and first and second contact pads between the gate lines;
forming a contact pad protecting layer on a surface of the first interlayer insulating layer and the first and second contact pads;
forming bit lines positioned on a second interlayer insulating layer provided on the contact pad protecting layer, extending in a direction perpendicular to the gate lines and connected to the first contact pad;
forming expanded contact openings formed in the second interlayer insulating layer between the bit lines, partially exposing the contact pad protecting layer and extending in a direction of the bit lines;
forming contact spacers formed on internal walls of the expanded contact openings and simultaneously forming expanded contact holes exposing the second contact pad; and
forming expanded contact plugs by filling the expanded contact holes with a conductive material.

16. The method of claim 15, wherein the contact pad protecting layer comprises a nitride layer.

17. The method of claim 15, further comprising:
before forming the bit lines:
forming contact plugs selectively connecting the bit lines to the first contact pad, wherein forming bit lines comprises patterning the bit lines to be electrically connected to the contact plugs.

18. The method of claim 17, wherein each of the contact plugs comprises a metal barrier layer and a metal layer stack.

19. The method of claim 15, wherein forming the contact spacers and the expanded contact holes comprises:
forming a spacer insulating layer conformally on internal walls of the expanded contact openings; and
anisotropically etching the spacer insulating layer and the contact pad protecting layer.

20. The method of claim 15, wherein the semiconductor substrate comprises a cell area and a peripheral area defined therein.

21. The method of claim 20, wherein the contact pad protecting layer is formed on the first interlayer insulating layer of the cell area and the first and second contact pads.

22. The method of claim 20, wherein forming the bit lines comprises:
forming a wiring connected to the semiconductor substrate of the peripheral circuit area and/or a gate electrode of the peripheral circuit area on the second interlayer insulating layer of the peripheral circuit area.
